(19) United States
(12) Patent Application Publication
(10) Pub. No.: US 2006/0087359 A1
(43) Pub. Date: Apr. 27, 2006

(54) Level shifting circuit

(76) Inventor: Martin Czech, Freiburg (DE)

Correspondence Address: O'Shea, Getz & Kosakowski, P.C.;Suite 912, 1500 Main Street, Springfield, MA, 01115, US

(21) Appl. No.: 11/259,630

(22) Filed: Oct. 26, 2005

(30) Foreign Application Priority Data
Oct. 26, 2004 (DE) 10 2004 052 092.5

(51) Int. Cl. H03L 5/00

(52) U.S. Cl. 327/333

(57) ABSTRACT

A circuit for level shifting comprises a first and second transistor (A, B), to each of which a signal can be applied, and a third and fourth transistor (C, D). The first and third transistors (C, D) are connected between a fundamental voltage (XUSS) and a supply voltage (XUDD) and have between them a first connection point (O1). The second and fourth transistors (B, D) are connected between the fundamental voltage (XUSS) and the supply voltage (XUDD), and have between them a second connection point (O2). The first connection point (O1) is connected to apply a control signal to the fourth transistor (D) at its control terminal, and the second connection point (O2) is connected to apply a control signal to the third transistor (C) at its control terminal. The circuit is characterized by at least one amplifier circuit (V) to amplify at least one of these control signals.

### CROSS REFERENCE TO RELATED APPLICATIONS

This application contains subject matter related to commonly assigned application Ser. No. ______, filed evendate herewith with Express Mail Certificate No. EV684062238US and designated Attorney docket number 3000-31. This application is hereby incorporated by reference.

### PRIORITY INFORMATION

This patent application claims priority from German patent application 10 2004 052 092.5 filed Oct. 26, 2004, which is hereby incorporated by reference.

### BACKGROUND OF THE INVENTION

The invention related to electronic circuits, and in particular to level shifting circuits.

A commonly known circuit for effecting level shifting is illustrated in FIG. 9. The circuit has two sections, each with its own working voltage. A first section 1 has a voltage system between a ground or fundamental voltage USS and a supply voltage UDD. A second section 2 has a second working voltage between a ground or fundamental voltage XUSS and a supply voltage XUDD. Various components are located between these working voltages.

In the first section 1, a control signal is applied and processed by inverters or other metal oxide semiconductor (MOS) circuits. The first section 1 thus supplies signals through two wires or connections CS1, CS2, to the actual circuit effecting level shifting that is formed by the second section 2 and additional components not shown. The signals supplied through the connections CS1, CS2 are thus based on the first section 1 of the circuit having the working voltage UDD-USS between the first fundamental voltage USS and supply voltage UDD. These signals are supplied to the second section 2, the components of which are operated at a working voltage XUDD-XUSS between the second fundamental voltage XUSS and the second supply voltage XUDD. Optionally, the two fundamental voltages USS and XUSS of the first and second sections 1, 2, are coupled by device N, which is often simply in the form of a wire that shorts the two fundamental voltages USS, XUSS. However, the device N may also, for example, be a resistance, diodes, bipolar transistors, or MOS transistors, as well as combinations thereof. The level shifting circuit illustrated in FIG. 9 has the purpose of providing a uniform reference potential for the entire circuit comprising first and second sections A, B.

The second section 2 comprises the essential components of a typical level-shifting circuit. A first transistor A and a third transistor C are connected in series between the fundamental voltage XUSS and the supply voltage XUDD. A first connection point O1 to provide a first signal O1 corresponding to the signals inputted from the left side is formed between first and third transistors A, C. In addition, a second transistor B and a fourth transistor D with a second connection point O2 between the two transistors B, D is connected between the fundamental voltage XUSS and the supply voltage XUDD. As with the first connection point O1, the second connection point O2 serves to provide a signal, in particular, an information signal for additional components and/or circuit sections of the second section 2. The first and second connections CS1, CS2 to transfer signals from the first section 1 are connected to the base or control terminals of the first and second transistors A, B. Starting from the first connection point O1, a connection also leads to the control terminal of the fourth transistor D. Starting from the second connection point O2, a corresponding connection leads to the control terminal of the third transistor C. Typically, a circuit of this type also includes additional components such as diodes which are also in part taken into account as parasitic components in the design of the circuit.

The first and second transistors A, B, which are preferably in the form of NMOS transistors are driven by the signals or voltage potentials to the connections CS1 or CS2 such that one becomes blocking while the other correspondingly becomes conducting. The first and second transistors A, B are dimensioned such that they are always able to pull down the nodes or connection points O1, O2 toward the third or fourth transistors C, D attached to the supply voltage XUDD to the extent that the opposing fourth or third transistors D, C are driven up thereby, and the opposing connection points O2 or O1 are accordingly pulled up. This switches off the third or fourth transistor C, D acting as a “resistance.” The third and fourth transistors C, D are, for example, in the form of p-channel MOS transistors (i.e., PMOS). The third and fourth transistors C, D thus have a feedback effect that causes the level-shifting circuit finally to flip to a new state in which the two connection points O1, O2 can assume, or assume in a reverse manner, the potential of the supply voltage XUDD or the fundamental voltage XUSS. What is assumed is thus the full level corresponding to the control of the first and second transistors A, B. Based on the current triggering of the third and fourth transistors C, D by the first and second transistors A or B, and the feedback, it is thus possible to start with a circuit, that is, the first section 1 with the lower supply voltage UDD relative to the fundamental voltage USS and to produce a full excursion of the larger working voltage there between the fundamental voltage XUSS and the supply voltage XUDD on the side of the second section.

Level shifters are particularly important in CMOS circuits since signals even on the high working voltage side must have the full excursion in order to avoid cross currents. The transistors in the first section 1 are typically fabricated using a different technology option as compared to the transistors A-D in the second section 2. This second section is able to operate at the high voltage, in other words, it has a high threshold voltage, a high breakdown voltage, and thus a correspondingly thick oxide. Conversely, the transistors on the side of the first section 1 must not be operated at high voltage since they are designed for an earlier breakdown, a lower threshold voltage, and with a thin oxide.

A circuit of this type has the disadvantage, actually untypical for XMOS circuit technology, that the first and second transistors A, B during a switching action must first fight against the initially completely driven-up third or fourth transistors C, D in order to decrease the levels at the connection points O1, or O2. The result is that not only are there cross currents flowing, but there are also limitations on the dimensioning of the transistors A-D. The first and second transistors A, B must be dimensioned to be strong enough that, even in the most unfavorable case (i.e., with a low supply voltage in the first section 1 and high supply voltage XUDD in the second section 2, high ambient temperatures, and a corresponding process position) the connection points O1, O2 end up low enough to trigger the feedback effect. Analogously, the third and fourth transistors C, D, must accordingly be weakly dimensioned. The circuit thus inherently has a CMOS-atypical asymmetry between the NMOS transistors and the PMOS transistors. This results in a large area requirement for the design of this circuit and also requires a greater throughput time than, for example, in an inverter using the same technology. The circuit is thus also not suitable for driving larger loads since the asymmetry manifests itself in large deviating rise times and fall times. The asymmetry is particularly evident and injurious when the working voltage UDD-USS in the first section 1 becomes increasingly smaller relative to the working voltage XUDD-XUSS of the second section 2. As a result, the first and second transistors A, B are barely controlled—with the result that only very small currents are allowed. Consequently, the third and fourth transistors C, D must be designed very weakly, thereby resulting in a no-longer-tolerable time response for the circuit.

The transistors C, D of a weakly dimensioned design also cause the output nodes or the two connection points O1, O2 to become sensitive to parasitics. The first and second transistors A, B must therefore be designed to be extremely strong, so that the necessary transistor sizes are sometimes ridiculous. Where there is a very large difference between the working voltage UDD-USS of the first section 1 and the working voltage XUDD-XUXX of the second section 2, it may also happen that a circuit of known design will no longer function. This is a growing problem in light of the continuing miniaturization or smaller dimensioning of transistors.

Therefore, there is a need for a level shifting circuit that has an improved design and functionality.

### SUMMARY OF THE INVENTION

A circuit for effecting level shifting, comprises a first and second transistor, to each of which a signal can be applied, and a third and fourth transistor. The first and third transistors are connected between a fundamental voltage and a supply voltage and have between them a first connection point. The second and fourth transistors are connected between the fundamental voltage and the supply voltage and have between them a second connection point. The first connection point is connected to apply a control signal to a control terminal of the fourth transistor, and the second connection point is connected to apply a control signal to a control terminal of the third transistor. The circuit has at least on amplifier circuit to amplify at least one of the control signals.

The amplifier circuit may include at least one amplifier connected between one of the connection points and the control terminal of the transistor associated therewith.

The amplifier circuit may include at least one pulse shaper and/or pulse generator that is connected between one of the connection points and the control terminal of the transistor associated therewith.

The amplifier circuit may include at least one amplifier and at least one pulse shaper and/or pulse generator, wherein the amplifier is connected between one of the connection points and the control terminal of the fourth or third transistor associated therewith, and wherein the pulse shaper and/or pulse generator is connected between one of the connection points and an additional fifth or sixth transistor, wherein the additional transistor is connected in parallel with the fourth or third transistor which is driven by the amplifier from the same connection point.

The pulse shaper and/or pulse generator may be connected following the amplifier and receive an amplified control signal from the amplifier.

The amplifier circuit may control one or more transistors connected in parallel with transistors that are each driven from the same connection point.

The amplifier circuit may include multiple inputs to apply one control signal each from one of the connection points, and at least one, multiple output to output amplified or shaped control signals to control inputs of the third and/or fourth and/or additional transistors.

The first and the second transistors each may have a control terminal to apply one voltage signal each from the voltage system having a lower voltage than that between the fundamental voltage and the supply voltage.

The amplifier circuit may be designed and connected so as to provide an amplified and/or shaped control signal. A differential amplifier may be included having a circuit to amplify a differential signal and having an amplifier of this type.

A phase shifter circuit or a differential amplifier may be operated in which control signals are amplified and/or shaped by cross-coupled transistors before they are applied to a control terminal of the associated transistor.

The control signals may be applied, as amplified and/or shaped, to the corresponding control terminal in a time-limited manner.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 is a schematic illustration of a first circuit for effecting level shifting and having an amplification arrangement;

FIGS. 2A and 2B are plots of the characteristics of various amplification elements used in the circuit of FIG. 1;

FIGS. 3-5, 8 are schematic illustrations of alternative embodiments;

FIGS. 6, 7 show individual circuit elements of the circuits illustrated; and

FIG. 9 shows a circuit based on prior art.

### DETAILED DESCRIPTION OF THE INVENTION

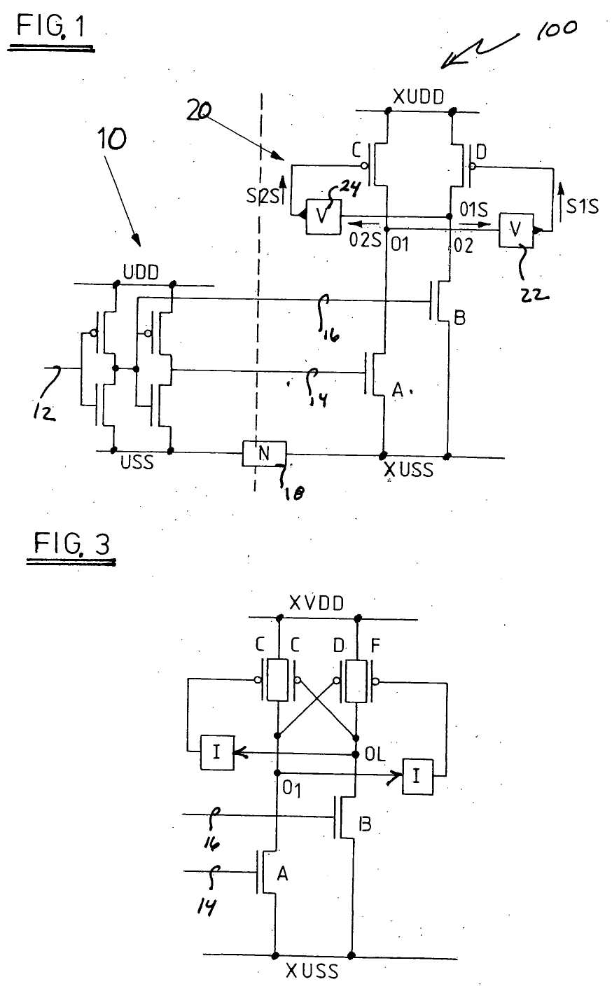

FIG. 1 illustrates a level shifting circuit 100. The circuit includes at least two sections, each having its own working voltage. A first section 10 has a voltage system between a ground or fundamental voltage USS and a supply voltage UDD. A second section 20 has a second working voltage between a ground or fundamental voltage XUSS and a supply voltage XUDD. Various circuit components are located between these working voltages.

In the first section 10, a control signal on a line 12 is applied and processed by inverters or other MOS circuits. The first section 10 thus supplies signals via lines 14, 16 to the actual circuit for effecting level shifting which is formed by the second section 20 and additional components not shown. The signals on the lines 14, 16 are thus based on the first section 10 of the circuit having the working voltage UDD-USS between the first fundamental voltage USS and the supply voltage UDD. These signals are supplied to the second section 20, the components of which are operated at a working voltage XUDD-XUSS between the second fundamental voltage XUSS and the second supply voltage XUDD. For improving a level-shifting circuit, the components of the first section 10 are not of major significance and are thus described simply to facilitate an understanding of a conventional circuit.

Optionally, the two fundamental voltages USS and XUSS of the two sections 10, 20 may be coupled to each other, for example, by the device N 18 which may also simply be a wire that shorts the two fundamental voltages USS and XUSS. However, the device N 18 may also be a resistance, diodes, bipolar transistors, or MOS transistors, as well as combinations thereof. The level-shifting circuit shown in FIG. 1 provides a uniform reference potential for the entire circuit comprising the first and second sections 10, 20.

The second section 20 comprises the essential components of a level-shifting circuit. A first transistor A and third transistor C are connected in series between the fundamental voltage XUSS and the supply voltage XUDD. A first connection point O1 to provide a first signal O1 corresponding to the signals received from the left side is formed between the first and third transistors A, C. In addition, a second transistor B and fourth transistor D with a second connection point O2 between the two transistors B, D are connected between the fundamental voltage XUSS and the supply voltage XUDD.

The second connection point O2 functions analogously to the first connection point O1 to provide an information signal for additional components and/or circuit sections of the first section 20. The first and second connections CS1, CS2 are connected to the base or control terminals of the first and third transistors A, B.

In addition, a connection leads to the control terminal of the fourth transistor D from the first connection point O1. An amplification circuit, or a component of a larger-dimensioned amplification circuit 22, may be interconnected between this connection leading from the first connection point O1 to the control terminal of the fourth transistor D. In response to even a small voltage change at the first connection point O1, the amplification circuit causes an amplified control signal to be applied to the control terminal of the fourth transistor D such that the transistor switches more quickly than with known circuits.

A corresponding connection leads from the second connection point O2 through a corresponding amplifier circuit 24 or amplifier arrangement to the control terminal of the third transistor C. Typically, a circuit of this type comprises additional components such as diodes, which are taken into account in part as well in the form of parasitic components when designing the circuit.

The first and second transistors A, B, which are preferably in the form of NMOS transistors, are driven by the signals or voltage potentials to the connections CS1 or CS2 such that one becomes blocking and the other conducting. The first and second transistors A, B are dimensioned such that, in connection with the corresponding amplifier circuits V, they are able to pull down the nodes or connection points O1, O2 towards the third and fourth transistors C, D attached to the supply voltage XUDD to the extent that the opposing fourth or third transistors D, C are driven up thereby and accordingly pull-up opposing connection points O2 or O1. This ultimately switches off the one third or fourth transistor C, D exerting a “resistance.” The third and fourth transistors may be, for example, PMOS transistors. The third and fourth transistors C, D thus have a feedback effect that ultimately flips the level-shifting circuit to a new state in which the two connection points O1, O2 assume, or assume in a reverse fashion, the potential of the supply voltage XUDD or the fundamental voltage XUSS. What is thus assumed is the full level corresponding to the control of the first and second transistors A, B. Based on the current triggering of the third and fourth transistors C, D by the first or second transistors A or B and on the feedback, it is thus possible to produce from a circuit (i.e., from the first section 1 with small supply voltage UDD relative to fundamental voltage USS) a full excursion of the larger working voltage between its fundamental voltage XUSS and the supply voltage XUDD on the side of the second section 20.

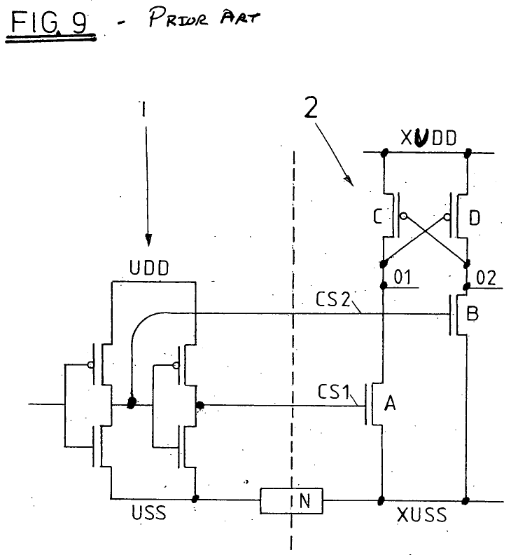

The components of the amplifier circuit, based on the simplified embodiment illustrated in FIG. 1, entail simple amplifiers V. The amplifiers V monitor the levels at the nodes or connection points O1, O2, and in response to even small dips apply an amplified, preferably full signal, to the associated fourth or third transistors D, C as a control signal. As a result, the first and second transistors A, B no longer need be dimensioned as strongly as required of the prior art circuit of FIG. 9. In addition, the remaining third and fourth transistors C, D no longer need to be dimensioned as weakly as those in the circuit of FIG. 9.

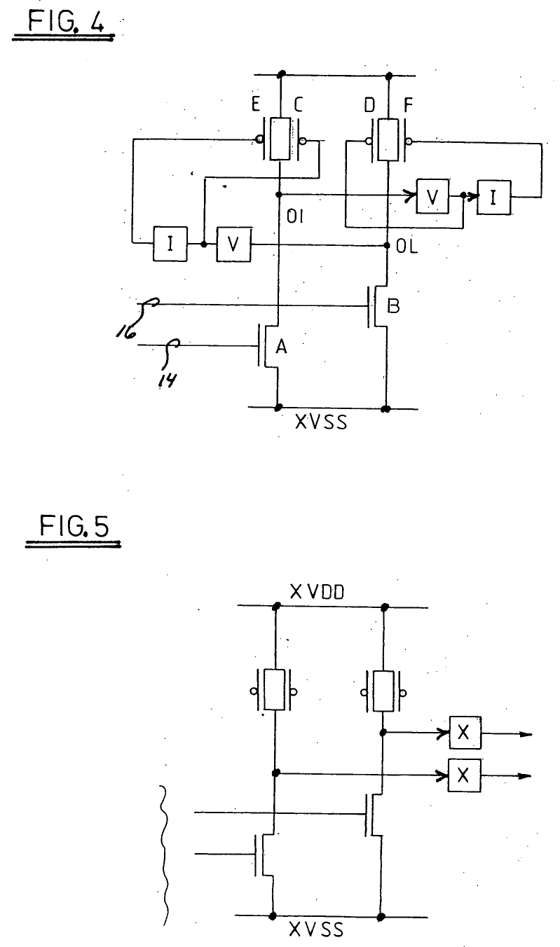

In addition to the simple amplifiers V in the form of amplifier circuit components like those of the embodiment of FIG. 1, it is also possible to employ, additionally or alternatively, pulse shapers and/or pulse generators as pulse stages I, as illustrated for the circuits in FIGS. 3 and 4. Such pulse stages can be used, in particular, to control the control terminals of additional transistors E, F, preferably, located in parallel to the third and fourth transistors C, D. The pulse stages I can pull-up the nodes or connection points O1, O2 quickly, as a result of which the entire breakover process is significantly accelerated and the full level is quickly achieved everywhere.

In addition to the various circuits of FIGS. 1, 3 and 4, other amplifier elements X can be connected between the connection points O1, O2 and corresponding signal outputs in order to decouple the core of the circuit from the driving circuits and thereby prevent feedback to the core.

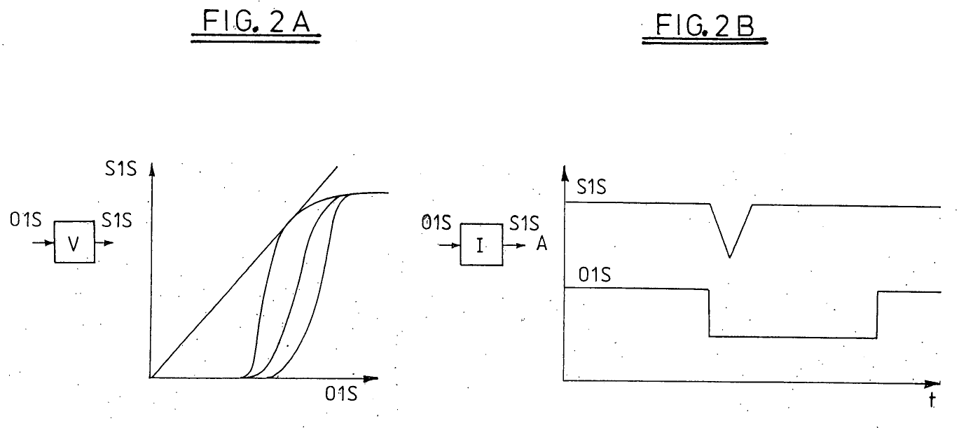

FIG. 2A shows the characteristic for the amplifier V. The amplifiers within a circuit are preferably, however, not necessarily designed with the identical gain properties. The characteristic illustrated is a nonlinear characteristic such that a small decrease of the input voltage O1S at the input of the amplifier V lowers controlled transistor C strongly downward, preferably, to the point of saturation. As a result, even given only a slight decrease of the levels at the connection points O1, O2 the respective opposing fourth or third transistors D, C are driven more quickly, which action again switches off the other (i.e., the third or fourth transistor C, D through feedback) and thus enables or accelerates lowering to fundamental voltage XUSS.

FIG. 2B illustrates the function of the pulse shaper I. For example, a falling edge of the signal at the connection point O1, and thus at the input of the pulse shaper I, results in a short pulse at the output of pulse shaper I, wherein the pulse in the form of a pulse-shaped control signal S1S is applied to the control input of the associated transistor F. As a result, the additional transistors E, F illustrated in FIG. 3 are actively switched by the respective associated pulse shaper I at the instant of break-over such that they activate short. As a result, the pull-up of the corresponding connection point O1, O2 is correspondingly fast.

FIG. 4 illustrates a preferred embodiment in which the amplifiers V and the additional pulse shapers I are connected between each of the connection points O1, O2 and the corresponding transistors D, F, or C, E. As in the case of FIG. 3, again only those components are described that differ from the embodiment of FIG. 1. In terms of additional components, reference is made to the description of FIG. 1. In the circuit of FIG. 4, the amplifiers V again provide for an early breakover, that is, in particular, a breakover point during voltage analysis by the amplifier circuit. The pulse shapers I connected on the output side or in parallel use the transistors E, F as auxiliary transistors to implement the breakover more quickly.

In the circuits having the additional transistors E, F as auxiliary transistors, these transistors should not become active on the pull-down side since this may retard or even stop each action. In addition, the pulse shapers I should control the optionally strongly dimensioned additional transistors E, F only for a brief instant, and in particular preferably at the most appropriate instant. If the additional transistors E, F were always active, the first and second transistors A, B would essentially, or not at all, be able to move the associated connection points O1 or O2, with the result that any action would become impossible. Preferably, the circuits of FIG. 1, 3 or 4 are augmented by decoupling amplifiers in the form of additional amplifiers X that are outlined in FIG. 5. The additional amplifiers X shield the connection points O1, O2 from their loads.

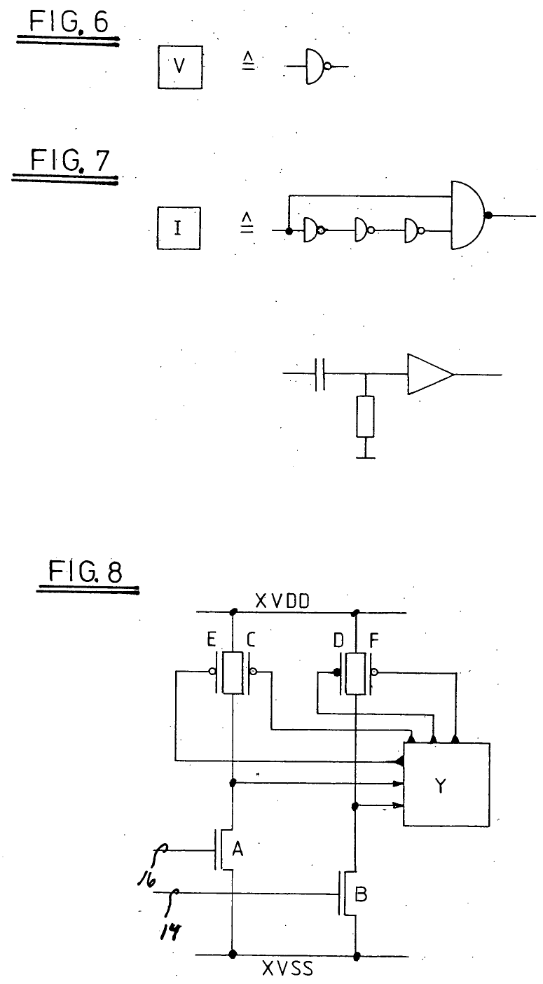

As in FIG. 6, the amplifiers V, X may include simple converters. As shown in FIG. 7, the pulse shapers I can include inverter chains with logic gates, as essentially known in the form of digital derivative units. In principle, it is also possible to implement a circuit as an analog derivative unit.

FIG. 8 illustrates that this concept can be implemented as an amplifier arrangement having any desired amplifier circuit Y, wherein the amplifier circuit Y detects the pull of the first and second transistors A, B, and initiates corresponding actions to switch the correspondingly associated third and fourth transistors C, D, as well as any optionally present additional transistors E, F, such that the poor response of the known level shifter core is improved.

The exemplary circuits, as well as any desired additional circuits working on the principle of amplifying the signal or voltage at the connection points O1, O2, can be employed, in particular, in any CMOS circuit that has two or more different working voltages. Particular advantages are achieved for circuits having high speed requirements and large differences between the UDD-USS and the XUDD-XUSS working voltages. This is true, for example, in the case of advanced CMOS processes of the 0.18 μm or 0.13 μm class in which the core voltage is only 1.8 V or 1.2 V, whereas the input and/or output voltage is, for example, 3.3 V.

Implementation of the present invention is not restricted to digital circuits. Analog circuits also require level converters of this type for digital control signals, et cetera, and can be designed analogously. Implementation is also possible for accelerating linear circuits (e.g., a differential amplifier). DMOS or VMOS circuits can also be equipped in this way with an amplifier or an amplifier circuit. The technique of the present invention can also be implemented for different variants of MOS processes.

It is possible to reverse the substrate type, whereby all the transistors are replaced by their complementary type. Application of the concept in NMOS and PMOS technologies is also possible.

In addition to the application in integrated circuits, application is also possible in discrete circuits with individual transistors or with small-scale-integration transistor modules. Application is also possible with bipolar transistors, in particular, when the amplifier circuit Y is designed accordingly as in FIG. 8, and the NMOS transistors are replaced by NPN structures or the PMOS transistors are replaced by PNP structures. The configuration of the various amplification elements V, I, X can then be arranged as desired at the core of the level shifter, in accordance with the best arrangement matching the design layout.

Although the present invention has been illustrated and described with respect to several preferred embodiments thereof, various changes, omissions and additions to the form and detail thereof, may be made therein, without departing from the spirit and scope of the invention.

What is claimed is:

1. A level shifting circuit, comprising
first and second transistors (A, B), to each of which a signal can be applied;
third and fourth transistors (C, D);
where the first and third transistors (A, C) are connected between a fundamental voltage (XUSS) and a supply voltage (XUDD), and have between them a first connection point (O1), and wherein the second and fourth transistors (B, D) are connected between the fundamental voltage (XUSS) and the supply voltage (XUDD), and have between them a second connection point (O2);
where the first connection point (O1) is connected to apply a first control signal to the fourth transistor (D), and the second connection point (O2) is connected to apply a second control signal to the third transistor (C); and
and at least one amplifier circuit (V; I; V, I; Y) that amplifies at least one of the first and second control signals.

2. The circuit of claim 1, where the amplifier circuit has at least one amplifier (V) that is connected between one of the connection points (O1, O2) and the control terminal of the transistor (D, C) associated therewith.

3. The circuit of claim 1, where the amplifier circuit comprises a pulse shaper and/or pulse generator (I) that is connected between the connection points (O1, O2) and the transistor (F, E) associated therewith.

4. The circuit of claim 2, where the amplifier circuit comprises at least one amplifier (V) and at least one pulse shaper and/or pulse generator, where the amplifier (V) is connected between one of the connection points (O1, O2) and the control terminal of the fourth or third transistors (D, C) associated therewith, and the pulse shaper and/or pulse generator is connected between one of the connection points (O1, O2) and an additional, fifth or sixth transistor (F, E), where the additional transistor (F, E) is connected in parallel with the fourth or third transistor (D, C) that is controlled from the same connection point (O1, O2) through the amplifier (V).

5. The circuit of claim 3, where the pulse shaper and/or pulse generator (I) is connected on the output side of the amplifier (V) and receives an amplified control signal from the amplifier (V).

6. The circuit of claim 1, where the amplifier circuit (I) controls one or more transistors (E, F) which are connected in parallel with the transistors (C, D) that are controlled from the respective same connection point (O2, O1).

7. The circuit of claim 1, where the amplifier circuit (Y) has multiple inputs to apply one of the respective control signals from one of the connection points (O1, O2), and at least one, preferably, multiple outputs to output amplified and/or shaped control signals to control inputs of the third and/or fourth and/or additional transistors (C, D, E, F).

8. The circuit of claim 1, where the first and second transistors (A, B) each have a control terminal to apply a respective voltage signal from a voltage system (1) having a lower voltage (UDD-USS) than between the fundamental voltage (XUSS) and the supply voltage (XUDD).
